(19) United States
(12) Patent Application Publication
(10) Pub. No.: US 2025/0203776 A1
(43) Pub. Date: Jun. 19, 2025

(54) SUBSTRATE STRUCTURE AND MANUFACTURING METHOD THEREOF

(71) Applicant: Unimicron Technology Corp., Taoyuan City (TW)

(72) Inventors: Chin-Sheng Wang, Taoyuan City (TW); Chih-Kai Chan, Taoyuan City (TW); Hsuan-Chung Chan, Taoyuan City (TW); Shih-Lian Cheng, New Taipei City (TW)

(73) Assignee: Unimicron Technology Corp., Taoyuan City (TW)

(21) Appl. No.: 18/650,103

(22) Filed: Apr. 30, 2024

Related U.S. Application Data
(60) Provisional application No. 63/609,882, filed on Dec. 14, 2023.

(30) Foreign Application Priority Data
Apr. 2, 2024 (TW) 113112493

(51) Int. Cl. H05K 1/11; H05K 3/00; H05K 3/40; H05K 3/42

(52) U.S. Cl. CPC H05K 1/116; H05K 3/007; H05K 3/4076; H05K 3/428; H05K 2201/09536; H05K 2203/0723; H05K 2203/1105; H05K 2203/1194; H05K 2203/1438; H05K 2203/1453

(57) ABSTRACT

A substrate structure includes a substrate and a vertical conductive connector. The substrate includes a material with a heat resistance temperature of 300° C. or greater. The vertical conductive connector penetrates through the substrate. The vertical conductive connector has a bonding structure extending toward the substrate. A manufacturing method of the substrate structure is also provided.

### CROSS-REFERENCE TO RELATED APPLICATION

This application claims the priority benefit of U.S. provisional application Ser. No. 63/609,882, filed on Dec. 14, 2023, and Taiwan application serial no. 113112493, filed on Apr. 2, 2024. The entirety of each of the above-mentioned patent applications is hereby incorporated by reference herein and made a part of this specification.

### BACKGROUND

### Technical Field

The disclosure relates to a substrate structure and a manufacturing method thereof.

### Description of Related Art

In substrate technology, vertical conductive connectors (such as plating through holes (PTH)) are often formed so that lines can be interconnected with each other in a thickness direction. However, due to the differences in material properties between the vertical conductive connectors and other components, it can cause problems such as low adhesion strength. Therefore, it is a challenge to improve the adhesion strength of the vertical conductive connectors in the substrate to enhance product reliability.

### SUMMARY

The disclosure provides a substrate structure and a manufacturing method thereof, which can effectively improve product reliability.

A substrate structure of the disclosure includes a substrate and a vertical conductive connector. The substrate includes a material with a heat resistance temperature of 300° C. or greater.

The vertical conductive connector penetrates through the substrate. The vertical conductive connector has a bonding structure extending toward the substrate.

A manufacturing method of a substrate structure of the disclosure at least includes the following steps. A substrate with a plurality of through holes and a conductive layer are provided.

The substrate is bonded to the conductive layer. An electro-plating process is performed to respectively form a vertical conductive connector in the plurality of through holes. An annealing process is performed to diffuse a plurality of first atoms in the vertical conductive connector toward the substrate to form a bonding structure.

Based on the above, the disclosure introduces the annealing process to diffuse the atoms in the vertical conductive connector to form the bonding structure extending toward the substrate. In this way, the adhesion strength between the vertical conductive connector and the adjacent components can be enhanced, thereby effectively improving product reliability.

In order to make the above-mentioned features and advantages of the disclosure clearer and easier to understand, the following embodiments are given and described in details with accompanying drawings as follows.

### BRIEF DESCRIPTION OF THE DRAWINGS

FIG. 1A to FIG. 1L are partial cross-sectional schematic diagrams of a partial manufacturing method of a substrate structure according to an embodiment of the disclosure.

FIG. 2A to FIG. 2L are partial cross-sectional schematic diagrams of a partial manufacturing method of a substrate structure according to another embodiment of the disclosure.

FIG. 3A to FIG. 3E are partial cross-sectional schematic diagrams of a partial manufacturing method of a substrate structure according to still another embodiment of the disclosure.

FIG. 4A to FIG. 4E are partial cross-sectional schematic diagrams of a partial manufacturing method of a substrate structure according to yet another embodiment of the disclosure.

### DESCRIPTION OF THE EMBODIMENTS

In the following detailed description, for the purpose of explanation and not limitation, exemplary embodiments revealing specific details are set forth to provide a thorough understanding of the various principles of the disclosure. However, it will be clear to those skilled in the art that, thanks to the disclosure, the disclosure can be implemented in other embodiments that depart from the specific details disclosed herein. In addition, descriptions of commonly known devices, methods, and materials may be omitted so as to clearly describe the various principles of the disclosure.

The disclosure is more fully described with reference to the drawings of the embodiments. However, the disclosure may be embodied in various forms and should not be construed as being limited to the embodiments described herein. The thickness, dimensions or size of layer or region in the drawings may be exaggerated for clarity. The same or similar reference numbers are used to denote the same or similar elements, and will not be repeatedly described in the following paragraphs.

The aforementioned and other technical contents, features and effects of the disclosure will be clearly presented in the following detailed description of each embodiment with reference to the drawings. Directional terms mentioned in the following embodiments, such as “up”, “down”, “front”, “back”, “left”, “right”, merely refer to directions in the accompanying drawings. Accordingly, the directional terms are used to illustrate rather than to limit the disclosure.

Unless expressly stated otherwise, any method described herein should not be construed as requiring to perform the steps in a particular order.

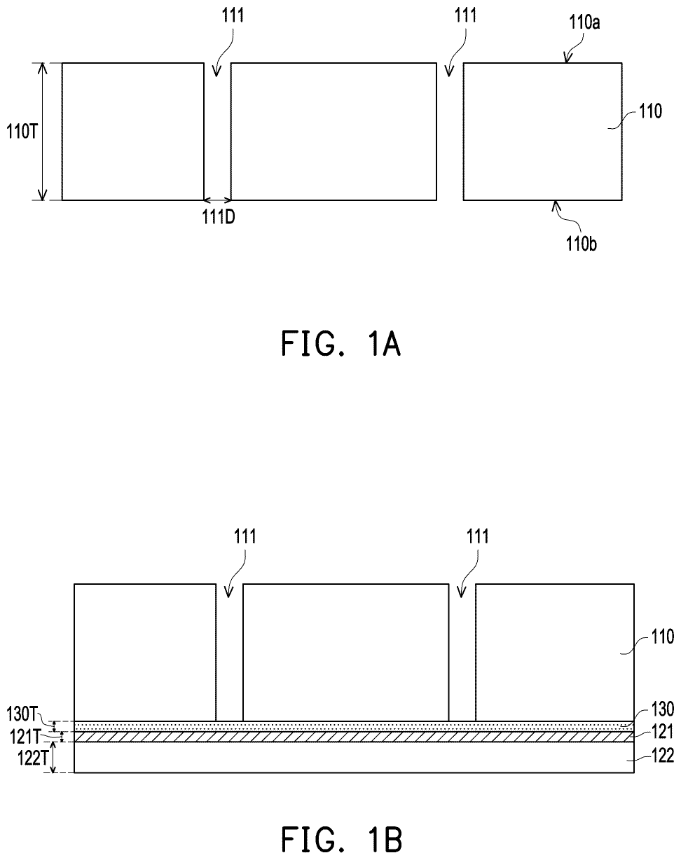

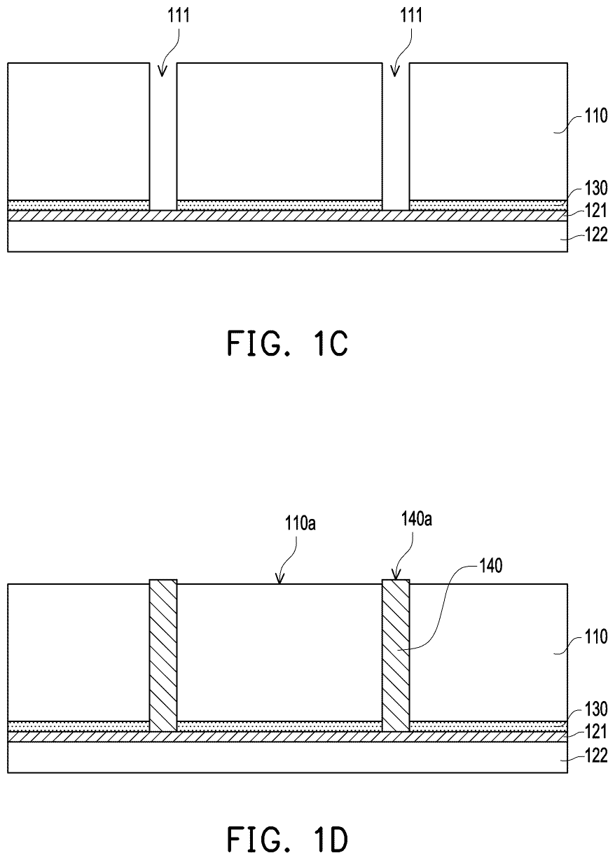

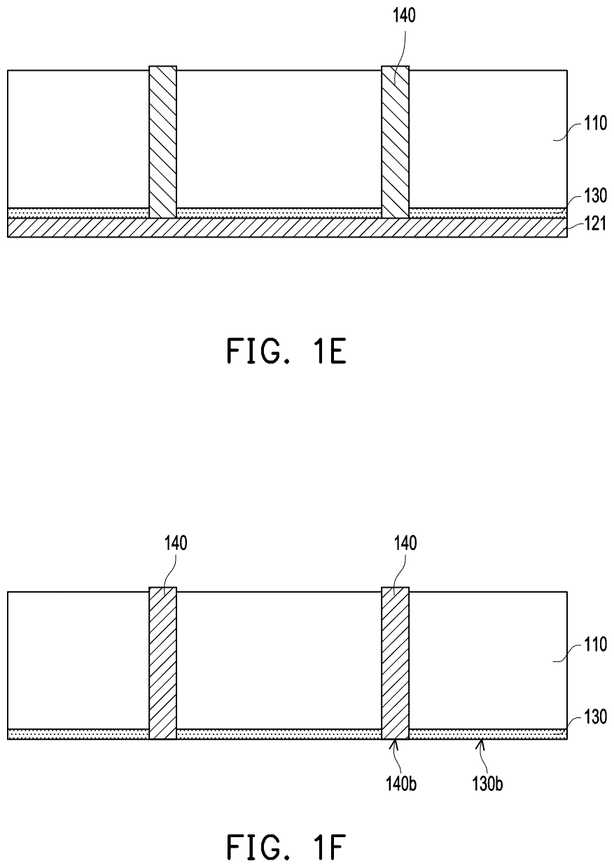

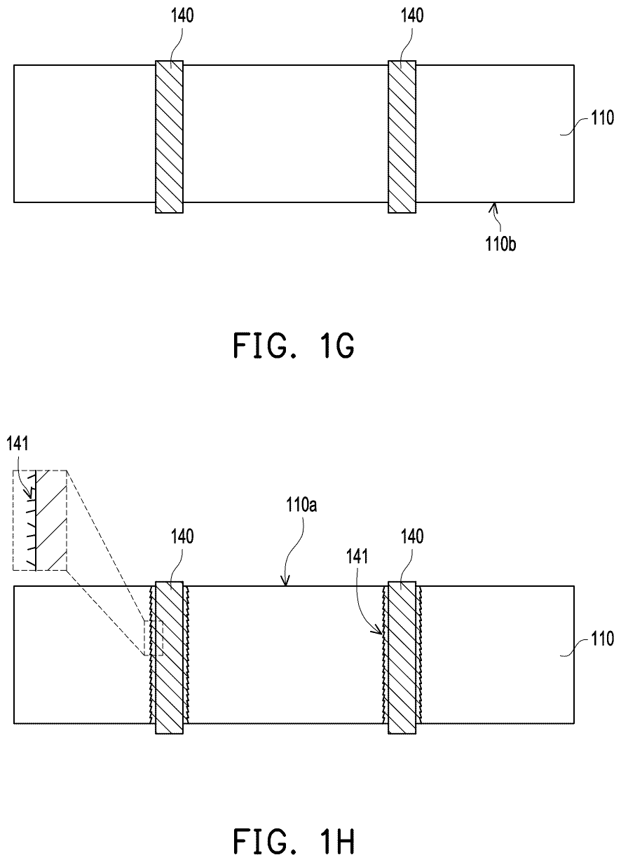

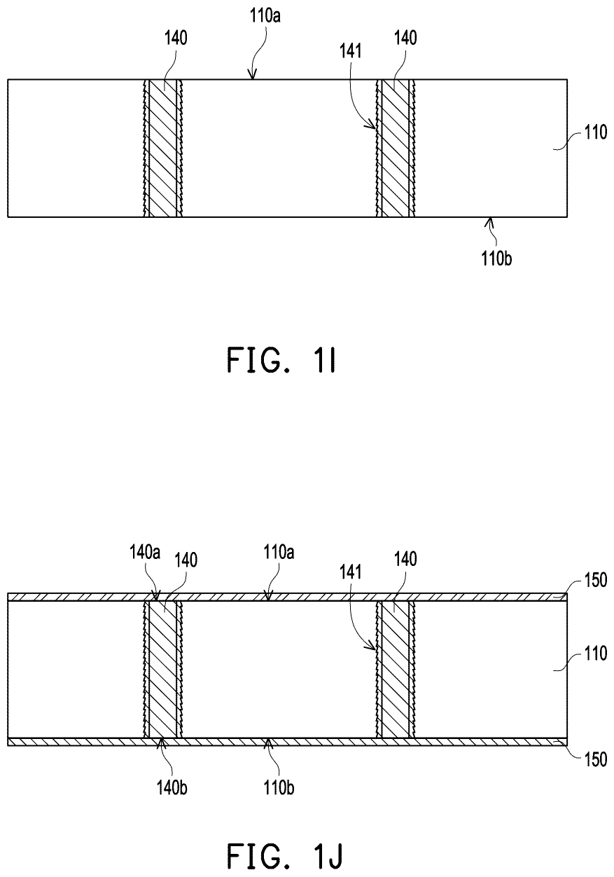

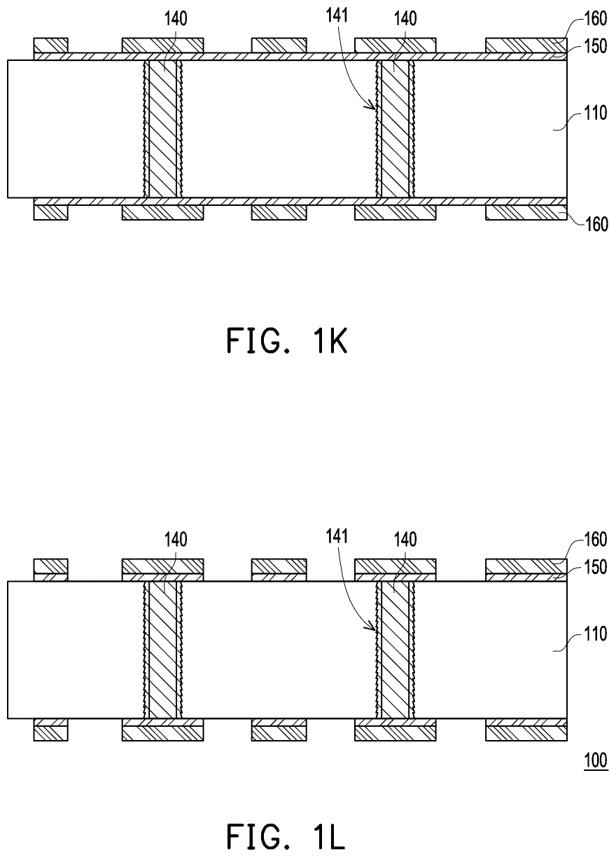

FIG. 1A to FIG. 1L are partial cross-sectional schematic diagrams of a partial manufacturing method of a substrate structure according to an embodiment of the disclosure.

Referring to FIG. 1A, a substrate 110 is provided. The substrate 110 includes a material with a heat resistance temperature of 300° C. or greater to reduce the probability of problems such as panel explosion when the subsequent annealing process is performed thereon. This ensures that the annealing process will not have obvious adverse effects on the substrate 110. Here, the heat resistance temperature may be 1500° C., and the substrate 110 may serve as the core layer of a substrate structure 100. The heat resistance temperature is a technical term that can be understood by those with ordinary knowledge in the technical field, and will not be repeated herein.

For example, a material of the substrate 110 includes glass, ceramic, liquid crystal polymer (LPC) or a combination thereof, but the disclosure is not limited thereto. The material of the substrate 110 can also be made of other suitable heat-resistant inorganic compounds and/or organic compounds.

In some embodiments, a thickness 110T of the substrate 110 is between 0.05 millimeters (mm) and 10 mm, but the disclosure is not limited thereto. The thickness 110T of the substrate 110 can be selected according to actual design requirements.

In FIG. 1A, the substrate 110 may be formed with a plurality of through holes 111. The through holes 111 penetrate through the substrate 110, for example, from an upper surface 110a of the substrate 110 to a lower surface 110b of the substrate 110 in a direction of the thickness 110T. Furthermore, the through holes 111 are formed by a drilling process or a similar process.

In some embodiments, a diameter 111D of the through hole 111 is between 0.05 mm and 0.5 mm, but the disclosure is not limited thereto. The diameter 111D of the through hole 111 can be determined according to actual design requirements.

In the embodiment, a seed layer composed of titanium, copper, palladium or similar metal materials is not formed on the through holes 111, the upper surface 110a of the substrate 110, and the lower surface 110b of the substrate 110.

In some embodiments, when the material of the substrate 110 is glass, since the surface roughness of the glass is low (for example, Ra<1 nanometer (nm)), it is difficult for the seed layer to be deposited thereon (whether using sputtered titanium/copper formed by a dry process or nanopalladium formed by a wet process, etc.), thus resulting in uneven deposition of the seed layer, such that the tensile force of the seed layer is reduced (such as the tensile force of sputtered titanium/copper is <0.3 (kg/cm)), and the adhesion strength cannot be effectively improved between the subsequent vertical conductive connector and the adjacent components thereof. Based on this, the formation of such a film layer can be omitted in the embodiment, and when such a film layer is omitted, the technical effect of improving the adhesion strength between the vertical conductive connector and the adjacent components thereof can still be achieved, but the disclosure is not limited thereto.

Referring to FIG. 1B, the substrate 110 is bonded to a conductive layer 121. For example, the conductive layer 121 can be attached to the substrate 110 through an adhesive layer 130, so the adhesive layer 130 is located between the conductive layer 121 and the substrate 110, and the through holes 111 can expose part of the adhesive layer 130.

In some embodiments, a thickness 121T of the conductive layer 121 is between 2 microns and 100 microns (such as 3 microns), and therefore can be regarded as a thin metal layer. At this thickness, defects (such as holes) are more likely to occur during use, so the conductive layer 121 can be further bonded to a carrier layer 122. A thickness 122T of the carrier layer 122 is between 1 micron and 25 microns (such as 18 microns). Therefore, the carrier layer 122 can reduce the probability of defects in the conductive layer 121 during the manufacturing process, but the disclosure is not limited thereto. Here, the conductive layer 121 and the carrier layer 122 can be bonded together through a release layer (not shown) to reduce the difficulty of subsequent removal of the carrier layer 122.

In some embodiments, a material of the conductive layer 121 includes copper or the like, a material of the carrier layer 122 includes copper or the like, and the adhesive layer 130 includes polyimide or the like, but the disclosure is not limited thereto.

In some embodiments, in order to improve the adhesion between the adhesive layer 130, the conductive layer 121, and the carrier layer 122, a lamination process may optionally be further used.

In some embodiments, a thickness 130T of the adhesive layer 130 is between 1 nanometer and 50 microns, but the disclosure is not limited thereto. The thickness 130T of the adhesive layer 130 can be determined according to actual design requirements.

Referring to FIG. 1C, the adhesive layer 130 at the bottom of the through holes 111 is removed to expose the underlying conductive layer 121. The removal method includes dry processes such as laser and plasma or wet processes such as de-smear, and the disclosure is not limited thereto.

Referring to FIG. 1D, an electro-plating process is performed to respectively form a vertical conductive connector 140 in the plurality of through holes 111. The electro-plating process may be to pass electricity through the conductive layer 121, so that a conductive material (such as copper) is formed upward from the bottom of the through hole 111 until it fills the through hole 111, and is higher than the top surface of the substrate 110 (such as the upper surface 110a), That is to say, a top surface 140a of the formed vertical conductive connector 140 is higher than the top surface (such as the upper surface 110a) of the substrate 110. In this way, in addition to ensuring that the conductive material completely fills the internal space of the through hole 111, it can also ensure that the circuits subsequently formed on the substrate 110 will not be recessed into the substrate 110, thereby enabling the product to have better electrical performance, but the disclosure is not limited thereto. Here, the conductive material includes copper or the like.

In the embodiment, since no seed layer is formed in the through hole 111, the vertical conductive connector 140 is physically connected to the substrate 110. In other words, the vertical conductive connector 140 can be in direct contact with the substrate 110.

In some embodiments, when the vertical conductive connector is formed through the seed layer, a larger thickness (for example, a thickness greater than 60 micrometers (μm)) is required to fully plate the metal in the through hole, and in this case it is difficult for substrate wirings to achieve thin lines with a line width/line spacing (L/S) less than 16/16 μm. However, through the method provided in the embodiment, the aforementioned problems can be overcome, and it is easier to meet the requirements of thin lines.

Referring to FIG. 1E, after performing the electro-plating process, the carrier layer 122 is removed from the conductive layer 121 through the release layer, for example, to expose the bottom surface of the conductive layer 121. However, the disclosure is not limited thereto. The carrier layer 122 may also be removed through other suitable methods.

Referring to FIG. 1F, the conductive layer 121 is removed by stripping or reduction with a suitable etching solution to expose a bottom surface 140b of the vertical conductive connector 140. The bottom surface 140b of the vertical conductive connector 140 may be coplanar with a bottom surface 130b of the adhesive layer 130.

Referring to FIG. 1G, the adhesive layer 130 is dipped in a suitable alkaline solution to remove the adhesive layer 130. In this way, the vertical conductive connector 140 will protrude from the lower surface 110b of the substrate 110. However, the disclosure It is not limited thereto. The adhesive layer 130 can also be removed through other suitable methods.

Referring to FIG. 1H, an annealing process is performed to diffuse a plurality of first atoms (not shown) in the vertical conductive connector 140 toward the substrate 110 to form a bonding structure 141. Furthermore, in the embodiment, the annealing process is introduced so that the first atoms of the vertical conductive connector 140 produce an atomic diffusion phenomenon toward the substrate 110. That is, as shown in the enlarged portion of FIG. 1H, the first atoms will move from an interface between the vertical conductive connector 140 and the substrate 110 to the gaps inside the substrate 110, and the first atoms will be arranged between the gaps to form the bonding structure 141 extending into the substrate 110. Under this mechanism, the bonding structure 141 may have irregular boundaries, and the plurality of first atoms are inserted into the gaps of the material of the substrate 110 to enhance the adhesion strength between the vertical conductive connector 140 and the adjacent substrate 110, thereby effectively improving product reliability. Here, the first atom includes a copper atom or other metal atoms.

In some embodiments, a maximum extension distance of the bonding structure 141 is between 0.1 nm and 100 nm, but the disclosure is not limited thereto. The extension distance of the bonding structure 141 will correspond to the process temperature and execution time of the annealing process.

In some embodiments, the annealing process is performed in nitrogen (N2) or other suitable ovens. The execution time is 30 minutes or greater (for example, between 30 minutes and 90 minutes), and the process temperature is 300° C. or greater (for example, between 300° C. min. and 600° C. min.), so that the first atoms can be diffused out reliably. However, the disclosure is not limited thereto. The parameter setting of the annealing process can be determined according to actual design requirements.

Referring to FIG. 1I, a planarization process is performed using a chemical mechanical polishing process (CMP) or the like to remove the excess vertical conductive connector 140 on the upper surface 110a and the lower surface 110b of the substrate 110. It should be noted that in embodiments not shown, the aforementioned planarization process may also be performed before the annealing process.

Referring to FIG. 1J, a seed layer 150 is formed on the substrate 110. For example, the seed layer 150 can fully cover and directly contact the upper surface 110a and the lower surface 110b of the substrate 110 and the top surface 140a and the bottom surface 140b of the vertical conductive connector 140. The seed layer 150 includes a sputtered titanium/copper layer or a copper layer formed by an electro-less plating process, but the disclosure is not limited thereto.

Referring to FIG. 1K, a circuit layer 160 is formed on the seed layer 150. The circuit layer 160 can be formed through a lithography process, such as semi-additive process (SAP) or patterned electro-plating, to form a circuit pattern with a plurality of openings, and the plurality of openings expose the seed layer 150. For example, the circuit layer 160 is located on the seed layer 150 on two sides of the substrate 110. Here, a material of the wiring layer 160 includes copper or the like.

Referring to FIG. 1L, the part of the seed layer 150 exposed by the plurality of openings of the circuit layer 160 is removed through a stripping process (such as using a suitable etching solution) to complete the circuit production.

After the above process, the production of the substrate structure 100 provided by the embodiment can be substantially completed. In the embodiment, the substrate structure 100 includes the substrate 110 and the vertical conductive connector 140 penetrating through the substrate 110. The vertical conductive connector 140 has the bonding structure 141 (formed by the annealing process) extending toward the substrate 110. In this way, the adhesion strength between the vertical conductive connector 140 and the adjacent substrate 110 can be enhanced, thereby effectively improving product reliability.

It must be noted here that the reference numerals and a part of the contents in the previous embodiment are applicable to the following embodiments, in which identical or similar reference numerals indicate identical or similar elements, and repeated descriptions of the same technical contents are omitted. For the detailed descriptions of the omitted parts, reference can be found in the previous embodiments, and no repeated description is contained in the following embodiments.

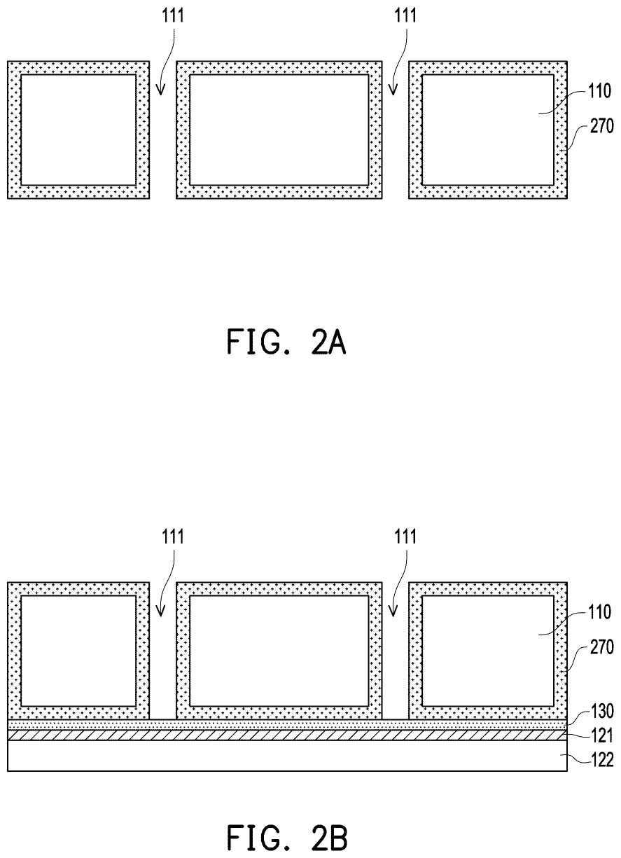

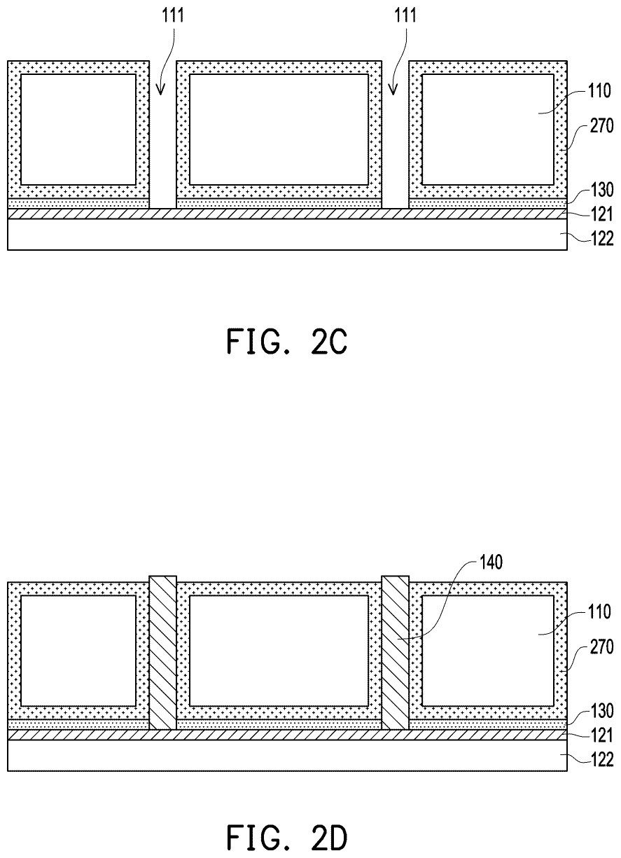

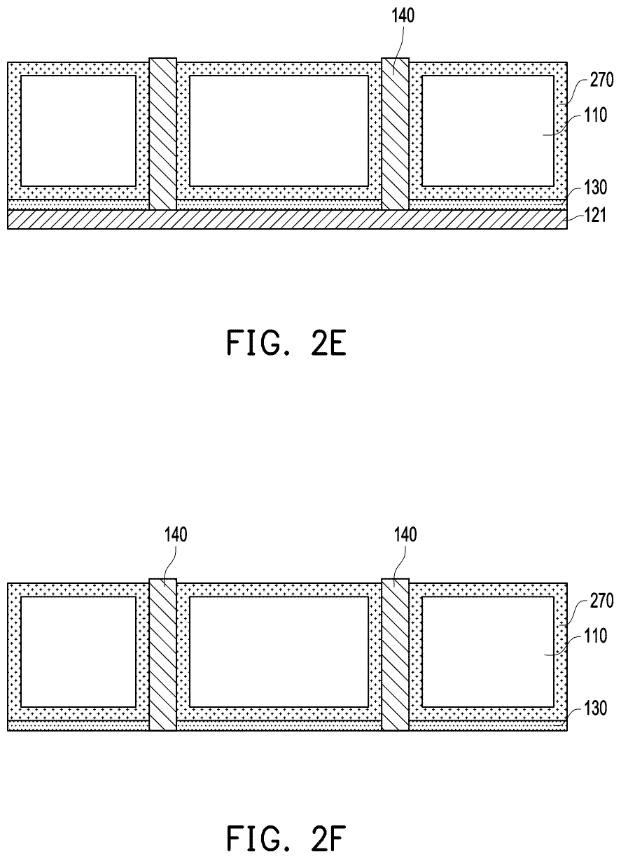

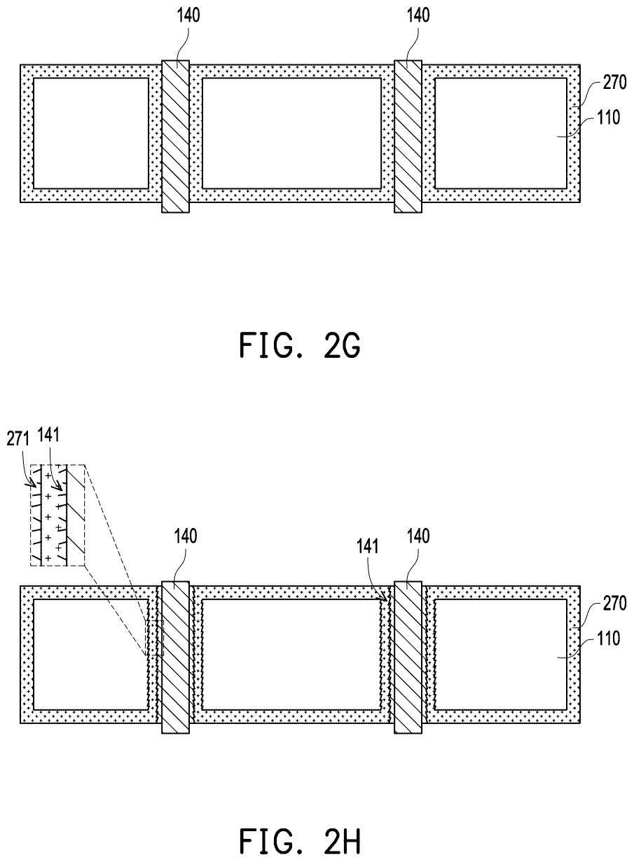

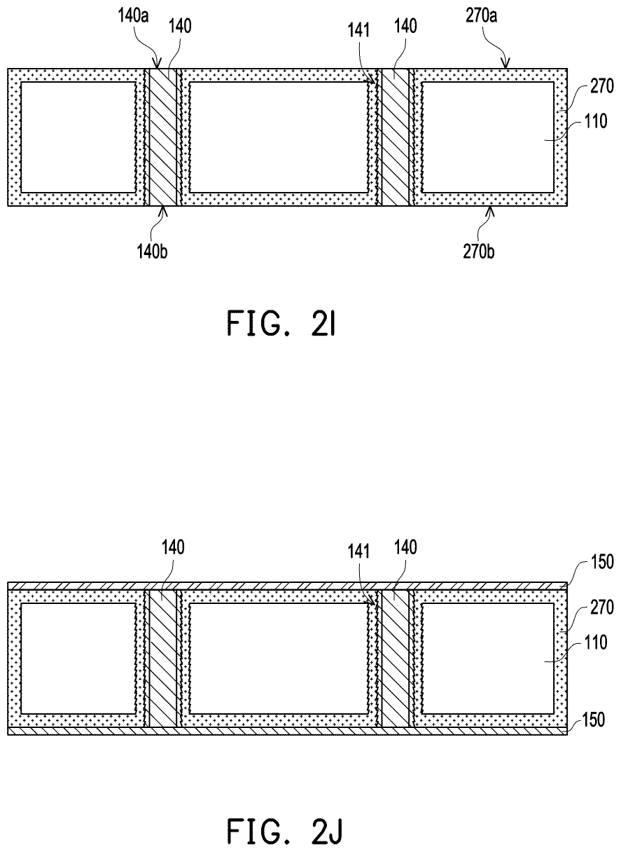

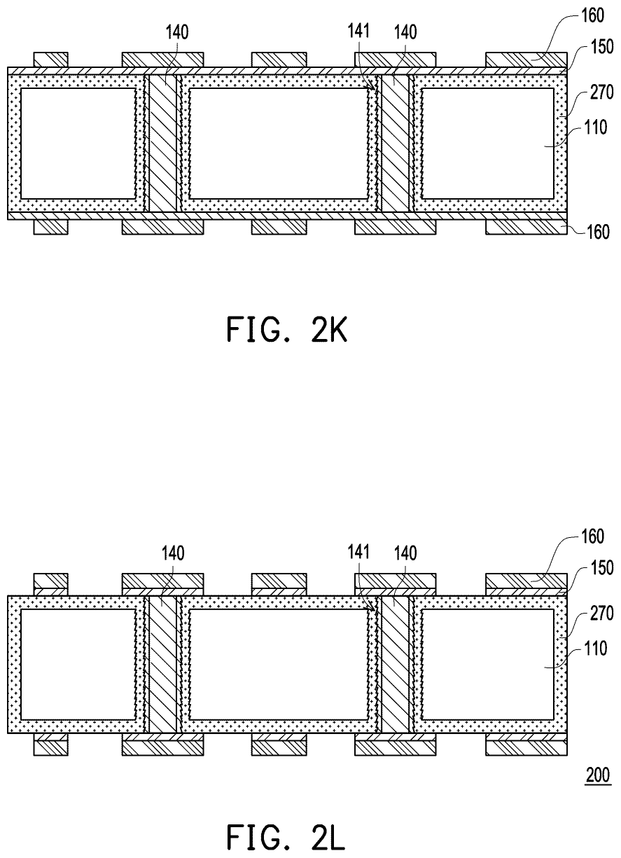

FIG. 2A to FIG. 2L are partial cross-sectional schematic diagrams of a partial manufacturing method of a substrate structure according to another embodiment of the disclosure.

Referring to FIG. 2A, similar to FIG. 1A, the difference lies in that after forming the through holes 111, a buffer layer 270 is formed on the substrate 110. The buffer layer 270 is formed, for example, by chemical vapor deposition (CVD), physical vapor deposition (PVD), atomic layer deposition (ALD), or other suitable processes.

In some embodiments, a material of the buffer layer 270 includes metal oxide (such as titanium oxide, zinc oxide, aluminum oxide, silicon oxide, or the like), metal (such as titanium), or a combination thereof, but the disclosure is not limited thereto.

In some embodiments, the buffer layer 270 may surround an outer surface of the substrate 110, so that no surface of the substrate 110 is exposed, but the disclosure is not limited thereto.

In an embodiment not shown, the buffer layer may have a multi-layer structure. For example, a titanium oxide layer may be formed first and then a titanium layer, but the disclosure is not limited thereto.

Referring to FIG. 2B and FIG. 2C, similar to FIG. 1B and FIG. 1C, the substrate 110 is bonded to the conductive layer 121 through the adhesive layer 130, and the adhesive layer 130 at the bottom of the through holes 111 is removed to expose the underlying conductive layer 121. In the embodiment, the buffer layer 270 is in direct contact with the adhesive layer 130 and separates the substrate 110 from the adhesive layer 130.

Referring to FIG. 2D, similar to FIG. 1D, the electro-plating process is performed to respectively form the vertical conductive connector 140 in the plurality of through holes 111. The buffer layer 270 is disposed between the substrate 110 and the vertical conductive connector 140 (such as in a direction perpendicular to the thickness), and the buffer layer 270 is in direct contact with the vertical conductive connector 140, so that the vertical conductive connector 140 is not physically connected to the substrate 110.

Referring to FIG. 2E, FIG. 2F, and FIG. 2G, similar to FIG. 1E, FIG. 1F, and FIG. 1G, after performing the electro-plating process, the carrier layer 122, the conductive layer 121, and the adhesive layer 130 are sequentially removed, and after the adhesive layer 130 is removed, the vertical conductive connector 140 will protrude from the bottom surface of the buffer layer 270.

Referring to FIG. 2H, similar to FIG. 1H, the annealing process is performed to diffuse the plurality of first atoms in the vertical conductive connector 140 toward the substrate 110 to form the bonding structure 141. Furthermore, the difference between the embodiment and the embodiment of FIG. 1H is that since the buffer layer 270 is located between the vertical conductive connector 140 and the substrate 110, after the annealing process is performed, the bonding structure 141 extends into the buffer layer 270 instead of into the substrate 110, so that the plurality of first atoms are inserted into the gaps of the material of the buffer layer 270. In addition, a plurality of second atoms (not shown) in the buffer layer 270 diffuse toward the substrate 110 after the annealing process is performed to form another bonding structure 271, so that the plurality of second atoms are inserted into the gaps of the material of the substrate 110. In this way, the adhesion strength between the corresponding components can be further enhanced through the plurality of bonding structures 141 and 271. Here, the second atom includes titanium or aluminum, but the disclosure is not limited thereto.

For example, in the embodiment, the annealing process is introduced so that the first atoms of the vertical conductive connector 140 and the second atoms in the buffer layer 270 produce an atomic diffusion phenomenon toward the substrate 110. That is, as shown in the enlarged portion of FIG. 2H, the first atoms will move from an interface between the vertical conductive connector 140 and the buffer layer 270 to the gaps inside the buffer layer 270, and the second atoms will move from an interface between the buffer layer 270 and the substrate 110 to the gaps inside the substrate 110, so the bonding structures 141 and 271 both have irregular boundaries.

In some embodiments, the annealing process is performed in nitrogen or other suitable ovens. The execution time is 30 minutes or greater (for example, between 30 minutes and 90 minutes), and the process temperature is 300° C. or greater (for example, between 300° C. min. and 600° C. min.), so that the first atoms and the second atoms can be diffused out reliably.

In some embodiments, a maximum extension distance of the bonding structure 271 is between 0.1 nm and 100 nm, but the disclosure is not limited thereto. The extension distance of the bonding structure 271 will correspond to the process temperature and execution time of the annealing process.

Referring to FIG. 2I, similar to FIG. 1I, the planarization process is performed to remove the excess vertical conductive connector 140 on the buffer layer 270, so that a top surface 270a of the buffer layer 270 is coplanar with the top surface 140a of the vertical conductive connector 140, and a bottom surface 270b of the buffer layer 270 is coplanar with the bottom surface 140b of the vertical conductive connector 140.

Referring to FIG. 2J, FIG. 2K, and FIG. 2L, similar to FIG. 1J, FIG. 1K, and FIG. 1L, the sequentially stacked seed layer 150 and circuit layer 160 are formed on the substrate 110, and the part of the seed layer 150 exposed by the plurality of openings of the circuit layer 160 is removed through the stripping process (such as using a suitable etching solution) to complete the circuit production. After the above process, the production of a substrate structure 200 provided by the embodiment can be substantially completed.

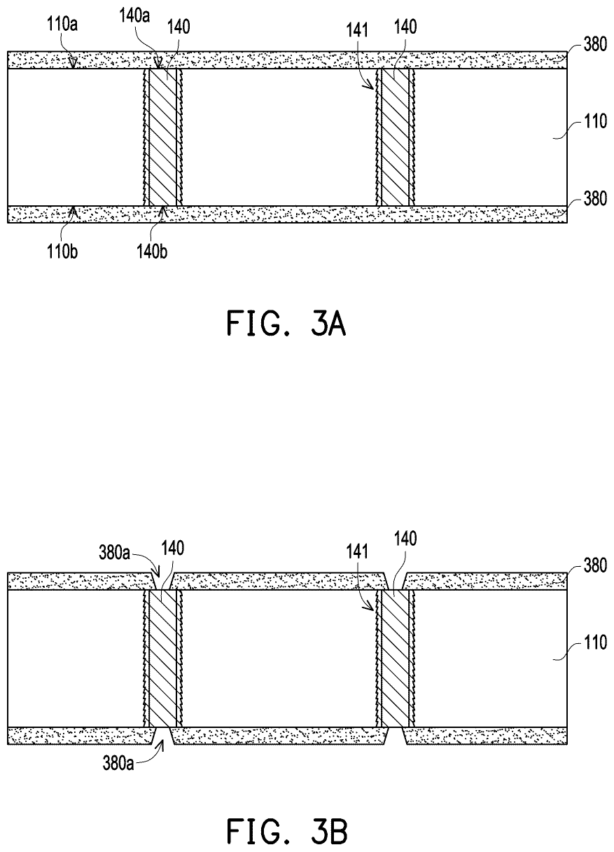

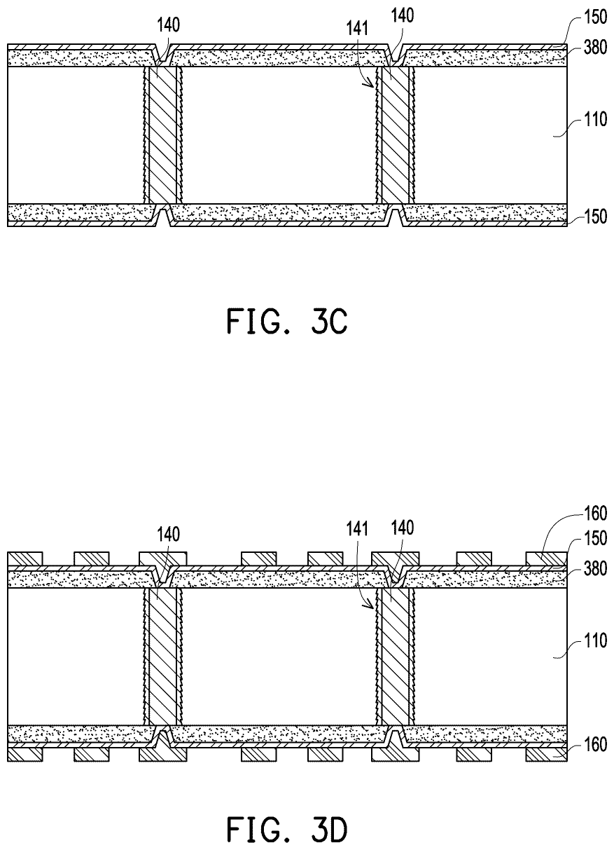

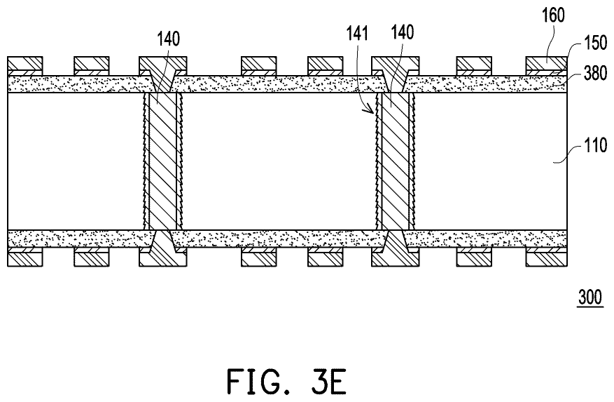

FIG. 3A to FIG. 3E are partial cross-sectional schematic diagrams of a partial manufacturing method of a substrate structure according to still another embodiment of the disclosure. Specifically, FIG. 3A to FIG. 3E illustrate the production of the structure following the steps of FIG. 1I.

Referring to FIG. 3A, after performing the annealing process, an insulating layer 380 is formed on the substrate 110. The insulating layer 380 can be formed by a lamination process using ajinomoto build-up film (ABF) material or a slit coating process using photo imageable dielectric (PID) material, but the disclosure is not limited thereto.

For example, the insulating layer 380 can fully cover and directly contact the upper surface 110a and the lower surface 110b of the substrate 110 and the top surface 140a and the bottom surface 140b of the vertical conductive connector 140, but the disclosure is not limited thereto.

Referring to FIG. 3B to FIG. 3E, first, as shown in FIG. 3B, a plurality of openings 380a are formed in the insulating layer 380 on two sides of the substrate 110 to expose the vertical conductive connector 140. Then, as shown in FIG. 3C to FIG. 3E, similar to FIG. 1J to FIG. 1L, the sequentially stacked seed layer 150 and circuit layer 160 are formed on the substrate 110, and the part of the seed layer 150 exposed by the plurality of openings of the circuit layer 160 is removed through the stripping process to complete the circuit production. After the above process, the production of a substrate structure 300 provided by the embodiment can be substantially completed.

In some embodiments, the bottom of the opening of the insulating layer 380 may be further cleaned, such as through a de-smear process or a plasma process, so that the vertical conductive connector 140 is more reliably exposed, but the disclosure is not limited thereto.

In the embodiment, the circuit layer 160 formed on the insulating layer 380 can penetrate through the insulating layer 380 to be in direct contact with and electrically connected to the vertical conductive connector 140. That is, the insulating layer 380 is located between the circuit layer 160 and the substrate 110, and the circuit layer 160 is only in direct contact with the vertical conductive connector 140, so that the circuit layer 160 is not in direct contact with the substrate 110.

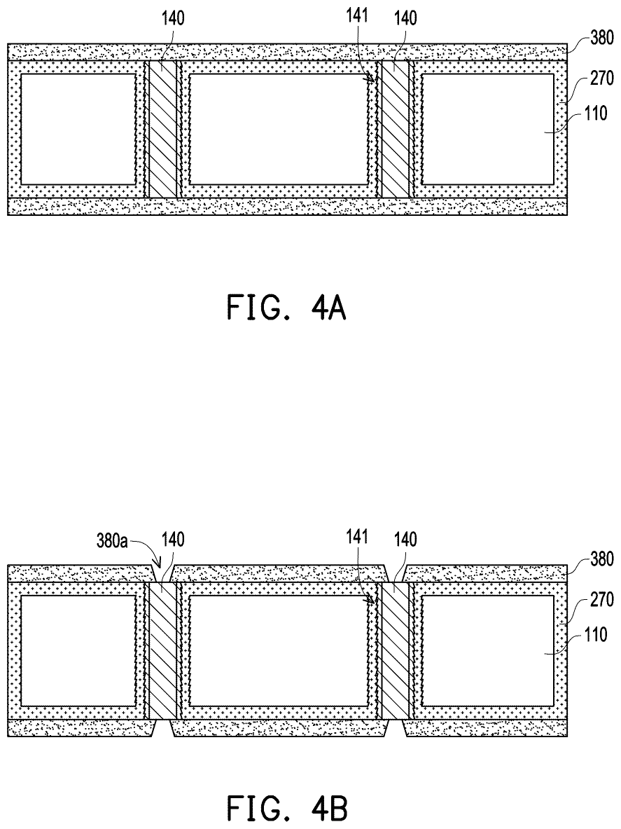

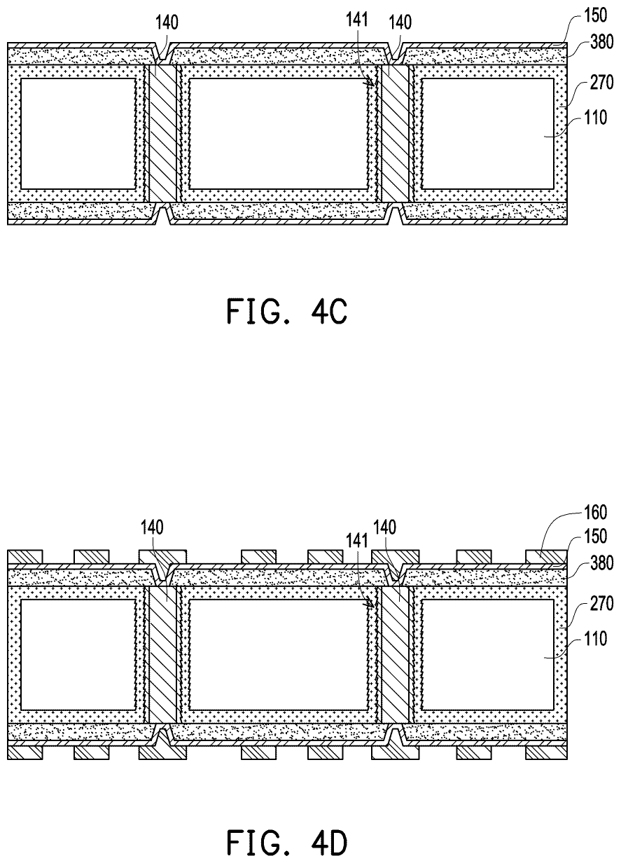

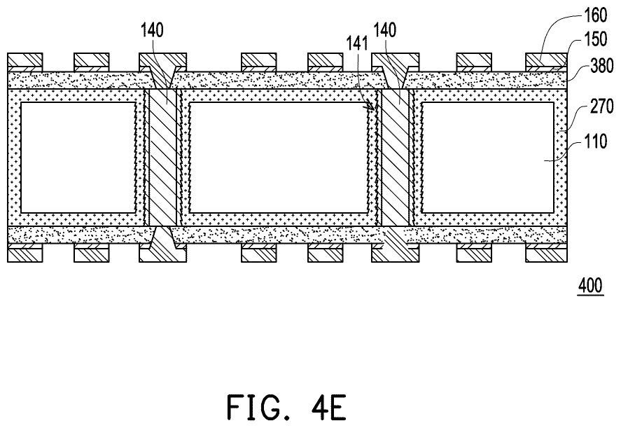

FIG. 4A to FIG. 4E are partial cross-sectional schematic diagrams of a partial manufacturing method of a substrate structure according to yet another embodiment of the disclosure. Specifically, FIG. 4A to FIG. 4E illustrate the production of the structure following the steps of FIG. 2I.

Referring to FIG. 4A and FIG. 4B, similar to FIG. 3A and FIG. 3B, after performing the annealing process, the insulating layer 380 is formed on the substrate 110. Then, the plurality of openings 380a are formed in the insulating layer 380 to expose the vertical conductive connector. 140. The insulating layer 380 may be in direct contact with the buffer layer 270.

Referring to FIG. 4C to FIG. 4E, similar to FIG. 3C to FIG. 3E, the sequentially stacked seed layer 150 and circuit layer 160 are formed on the substrate 110, and the part of the seed layer 150 exposed by the plurality of openings of the circuit layer 160 is removed through the stripping process (such as using a suitable etching solution) to complete the circuit production. After the above process, the production of a substrate structure 400 provided by the embodiment can be substantially completed.

To sum up, the disclosure introduces the annealing process to diffuse the atoms in the vertical conductive connector to form the bonding structure extending toward the substrate. In this way, the adhesion strength between the vertical conductive connector and the adjacent components can be enhanced, which can effectively improve product reliability.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A substrate structure, comprising:
a substrate, wherein the substrate comprises a material with a heat resistance temperature of 300° C. or greater; and
a vertical conductive connector, configured to penetrate through the substrate, wherein the vertical conductive connector has a bonding structure extending toward the substrate.

2. The substrate structure according to claim 1, wherein the bonding structure has irregular boundaries.

3. The substrate structure according to claim 1, wherein the vertical conductive connector comprises a plurality of first atoms, and the bonding structure is composed of an arrangement of the plurality of first atoms.

4. The substrate structure according to claim 1, wherein a maximum extension distance of the bonding structure is between 0.1 nanometers and 100 nanometers.

5. The substrate structure according to claim 1, wherein the bonding structure extends into the substrate.

6. The substrate structure according to claim 5, wherein the vertical conductive connector is physically connected to the substrate.

7. The substrate structure according to claim 1, further comprising a buffer layer disposed between the substrate and the vertical conductive connector, wherein the bonding structure extends into the buffer layer.

8. The substrate structure according to claim 7, wherein the vertical conductive connector is not physically connected to the substrate.

9. The substrate structure according to claim 7, wherein the buffer layer has another bonding structure extending into the substrate.

10. The substrate structure according to claim 9, wherein the vertical conductive connector comprises a plurality of second atoms, and the another bonding structure is composed of an arrangement of the plurality of second atoms.

11. The substrate structure according to claim 1, further comprising a circuit layer and an insulating layer, wherein the insulating layer is located between the circuit layer and the substrate, and the circuit layer is only in direct contact with and electrically connected to the vertical conductive connector.

12. A manufacturing method of a substrate structure, comprising:
providing a substrate with a plurality of through holes and a conductive layer;
bonding the substrate to the conductive layer;
performing an electro-plating process to respectively form a vertical conductive connector in the plurality of through holes; and
performing an annealing process to diffuse a plurality of first atoms in the vertical conductive connector toward the substrate to form a bonding structure.

13. The manufacturing method of the substrate structure according to claim 12, wherein an execution time of the annealing process is 30 minutes or greater.

14. The manufacturing method of the substrate structure according to claim 12, wherein a process temperature of the annealing process is 300° C. or greater.

15. The manufacturing method of the substrate structure according to claim 12, wherein the step before forming the vertical conductive connector does not comprise forming a seed layer.

16. The manufacturing method of the substrate structure according to claim 15, wherein the plurality of first atoms are inserted into gaps of a material of the substrate.

17. The manufacturing method of the substrate structure according to claim 12, wherein the step before bonding the substrate to the conductive layer further comprises:
forming a buffer layer on the substrate, wherein a plurality of second atoms in the buffer layer diffuse toward the substrate after performing the annealing process to form another bonding structure.

18. The manufacturing method of the substrate structure according to claim 17, wherein the plurality of first atoms are inserted into gaps of a material of the buffer layer, and the plurality of second atoms are inserted into gaps of a material of the substrate.

19. The manufacturing method of the substrate structure according to claim 12, wherein the step after performing the annealing process further comprises:
forming an insulating layer on the substrate; and
forming a circuit layer on the insulating layer, wherein the circuit layer penetrates through the insulating layer to be in direct contact with and electrically connected to the vertical conductive connector.

20. The manufacturing method of the substrate structure according to claim 12, wherein the step before bonding the substrate to the conductive layer further comprises:
providing a carrier layer; and
bonding the conductive layer to the carrier layer.
